(19) United States
(12) Patent Application Publication
(10) Pub. No.: US 2023/0418994 A1
(43) Pub. Date: Dec. 28, 2023

(54) METHOD AND SYSTEM FOR MODULARIZED MODELING OF EQUIPMENT ENTITIES IN SIMULATION FIELD BASED ON META-MODEL

(71) Applicant: Aerospace Internet of Things Technology Co.,Ltd, Beijing (CN)

(72) Inventors: Xiao YANG, Beijing (CN); Wenjun LI, Beijing (CN); Shumeng WANG, Beijing (CN); Fan ZHOU, Beijing (CN); Hao DONG, Beijing (CN); Lin GAO, Beijing (CN); Xuelin YANG, Beijing (CN); Xuefei WU, Beijing (CN)

(73) Assignee: Aerospace Internet of Things Technology Co.,Ltd, Beijing (CN)

(21) Appl. No.: 18/091,337

(22) Filed: Dec. 29, 2022

(30) Foreign Application Priority Data
Jun. 28, 2022 (CN) 202210739333.0

(51) Int. Cl. G06F 30/20

(52) U.S. Cl. CPC G06F 30/20

(57) ABSTRACT

Disclosed are a method and a system for modularized modeling of equipment entities in simulation field based on meta-model, where meta-modeling is combined with modularized modeling, and equipment simulation entities are divided into different model modules in terms of their physical attributes, behavior attributes, and task reliability attributes; a complete set of metadata is designed to characterize each dimensional attribute of the entity, and a meta-model representation protocol based on extensible markup language (XML) description is used to loosely couple the modeling of each module; after the simulation experiment is designed, the modules are bound for entity instantiation.

### CROSS-REFERENCE TO RELATED APPLICATIONS

This application claims priority to Chinese Patent Application No. 202210739333.0, filed on Jun. 28, 2022, the contents of which are hereby incorporated by reference.

### TECHNICAL FIELD

The present application belongs to the technical field of simulation entity modeling, and particularly relates to a method and a system for modularized modeling of equipment entities in simulation field based on meta-model.

### BACKGROUND

Recent years have seen a booming development of simulation technology in the military field, as well as a qualitative progress in the military training quality; however, such technology hasn't been successfully applied in securing logistics-equipment, and the demand for information construction of logistics-equipment is not well matched. Modeling is the foundation of simulation, and solid modeling is what should be solved first in applying simulation technology in the field of logistics-equipment security. Currently, the modeling of the logistics-equipment security simulation entities is not guided by a systematic methodology, resulting in a tight coupling of data, rules and algorithms in the model, and the model is confined to certain specific requirements with limited applicability; also, there is no unified standard protocol for the modeling process, and each unit acts blindly to duplicate modeling, which consumes a lot of human and material resources. Generally speaking, the existing approaches are inefficient in modeling and fail to meet the realistic needs of logistics-equipment security simulation, thus affecting the application of logistics-equipment security simulation technology.

Conventionally most of the logistics-equipment security simulation entity modeling adopts object-oriented modeling technology, following a modeling idea of abstracting the model data with the simulation object as the center, which is close to the learning approach of human understanding the world; this conventional object-oriented modeling approach is easy for people to understand and operate, but the entity data is not well abstracted in accordance with its functional attributes, and may easily lead to a class explosion. A modularized modeling approach uses module-oriented modeling technology to disassemble the object into different modules according to its attribute characteristics, and a module is encapsulated by its inherent functional attributes or the attributes of the task it undertakes. Module modeling provides better classification of entity data, object disassembly and encapsulation, and improves model reusability.

### SUMMARY

The present application provides a method and a system for modularized modeling of equipment entities in simulation field based on meta-model; according to the present application, logistics-equipment security simulation entity models are divided into three types of modules: physical attribute, behavior attribute and task reliability attribute, and each module model is described based on meta-model; after a simulation experiment is designed, required modules are then bound and assembled into a complete solid model.

To achieve the above objectives, the present application provides the following technical schemes:
a method for modularized modeling of equipment entities in a simulation field based on meta-model, including:
collecting data to be tested;
performing data pre-processing using the data to be tested, and then obtaining metadata;
using the metadata to perform attribute modeling, and obtaining a result of attribute modeling of a simulation entity of a module to be tested;
performing simulation entity model binding processing based on the result of attribute modeling of simulation entity, and thus obtaining simulation entity model; and
instantiating the simulation entity model to obtain a simulation result.

Optionally, the attribute modeling includes physical attribute modeling of simulation entity, behavior attribute modeling of simulation entity, and task reliability modeling.

Optionally, the physical attribute modeling of simulation entity includes attribute types of basic types and compound types;
the compound types include entity type, enumeration type and user-defined type;
the entity type includes an entity primary key, used for indicating an inter-entity relationship among entities such as a mounted entity, an assembled entity to a present entity, or an entity that the present entity is affiliated to, and a corresponding entity can be found in an entity instance manager through the entity primary key;
the enumeration types include optional attribute value list and attribute value, used for representing order enumeration type, equipment state enumeration type, and equipment working unit enumeration type; and
the user-defined type includes an attribute list, and the attribute list is commonly used by users and is convenient for attribute reuse.

Optionally, a method of the behavior attribute modeling of simulation entity includes: modeling entity behavior through a behavior tree, generating behavior modules, and constructing an event model for behavior to interact among entities with an event mechanism.

Optionally, a method of the task reliability modeling includes: modeling a reliability of equipment task execution through a reliability block diagram algorithm, and generating entity model task reliability module.

Optionally, a method of the simulation entity model binding processing includes:
binding equipment physical module and the behavior modules corresponding to a task being performed as well as task reliability modules, and the binding is achieved through an association model globally unique identifier (GUID).

Optionally, a method of instantiating the simulation entity model includes: inputting the simulation entity model into an instantiation factory, outputting an entity instance by a cloning method, and managing the entity instance with an instance manager to complete a modeling process, then loading the entity instance onto a simulation engine, and running to output simulation results.

The present application also provides a system for modularized modeling of equipment entities in simulation field based on meta-model, including:
a metadata acquisition module, a simulation entity attribute modeling module, a simulation entity model binding processing module, and a simulation entity model instantiation module;
the metadata acquisition module is used for acquiring metadata to be tested;
the simulation entity attribute modeling module is designed for performing attribute modeling based on the metadata, and obtaining a result of attribute modeling of a simulation entity of a module to be tested;
the simulation entity model binding processing module carries out simulation entity model binding processing based on the attribute modeling of the simulation entity of the module to be tested, then a simulation entity model is obtained;
the simulation entity model instantiation module is used for instantiating the simulation entity model to obtain a simulation result.

Optionally, the attribute modeling of simulation entity of the module to be tested in the simulation entity attribute modeling module includes: simulation entity physical attribute modeling, simulation entity behavior attribute modeling and task reliability modeling.

Optionally, a method of the simulation entity behavior attribute modeling in the simulation entity attribute modeling module includes: modeling entity behavior through a behavior tree, generating behavior modules, and constructing an event model for behavior to interact among entities with an event mechanism.

The application achieves the advantages that: a method and a system for modularized modeling of equipment entities in simulation field based on meta-model are provided in the present application, where the meta-model is described by extensible markup language (XML) and user-defined attribute structure is supported, the model is separated from the code to facilitate model modification and expansion as well as code maintenance; the model structure is simple and is applicable to heterogeneous platform simulation after converted by model adapter; entity physical attributes, behavior attributes and task reliability attributes can be independently modeled under the idea of modularized modeling, and the number of modules can be well expanded as required; the model modules can be flexibly configured according to the different tasks performed by the equipment to improve modeling efficiency and avoid duplicate modeling. The meta-model representation protocol of simulation entities and the modeling idea of modularized modeling, disassembly and aggregation designed in this application underpin the extensive application scenarios in the field of simulation; it is applicable in military, transportation, production and other simulation modeling fields, and the low-level duplicate construction is avoided and the resource sharing and reuse in the field of simulation is promoted.

### BRIEF DESCRIPTION OF THE DRAWINGS

For a clearer illustration of the technical schemes of the present application, the drawings below are briefly described for use in the embodiments, and it is obvious that the drawings in the following description are only some of the embodiments of the present application, and that other drawings may be obtained on the basis of these drawings without creative labor for those of ordinary skill in the art.

FIG. 1 shows a process of a method provided in one embodiment of the present application.

FIG. 2 is a tree model schematic diagram of an embodiment of this application.

FIG. 3 shows a schematic diagram of a reliability block diagram (RBD) modeling of one embodiment of the present application.

FIG. 4 is a schematic diagram of parallel path replacement of RBD of one embodiment of the present application.

FIG. 5 is a diagram illustrating a system composition of one embodiment of this application.

### DETAILED DESCRIPTION OF THE EMBODIMENTS

The following is a clear and complete description of the technical solutions in the embodiments of this application in conjunction with the accompanying drawings in the embodiments of this application. Obviously, the described embodiments are only a part of the embodiments of this application, and not all of them. Based on the embodiments in this application, all other embodiments obtained by a person of ordinary skill in the art without making creative labor shall fall within the protection of this application.

In order to make the above-mentioned objectives, features and advantages of this application more obvious and understandable, the application is described in further detail below in conjunction with the accompanying drawings and specific embodiments.

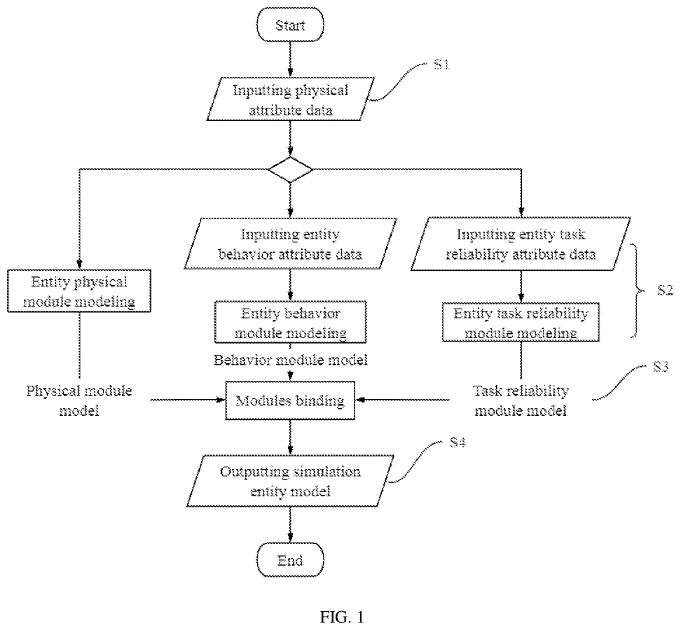

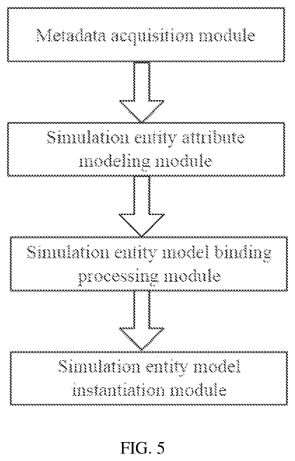

FIG. 1 shows a method for modularized modeling of equipment entities in simulation field based on meta-model, with specific operation illustrated as below, and a system for modularized modeling of equipment entities in simulation field based on meta-model is designed accordingly as shown in FIG. 5; according to the present embodiment, including:
S1, collecting metadata to be tested, where the metadata is collected by a metadata acquisition module in the present embodiment;
S2, generating an attribute modeling of a simulation entity of a module to be tested based on the metadata, and obtaining a result of attribute modeling of the simulation entity of the module to be tested, which is obtained by a simulation entity attribute modeling module in the present application;
among them, the attribute modeling of the simulation entity of the module to be tested includes: simulation entity physical attribute modeling, simulation entity behavior attribute modeling and task reliability modeling; and
a method of the simulation entity behavior attribute modeling includes: modeling entity behavior through a behavior tree, generating behavior modules, and constructing an event model for behavior to interact among entities with an event mechanism;
the present embodiment also specifically includes:
simulation entity physical attribute modeling, including describing the physical attribute of the entity through a set of complete metadata, and generating a physical module meta-model of the simulation entity;
the entity attribute is designed with a data structure of map type: map<string, Property>, which is convenient to find attributes by name; a former element is attribute name, a latter element is an attribute content, where the attribute content includes: attribute name, attribute type, and attribute value;
attribute types include:
basic type: {BYTE, INT, DOUBLE, LONG, LONGLONG, STRING, BOOL, TIME (time), VECTOR2 (two-dimensional vector), VECTOR3 (three-dimensional vector), QUATERNION (quaternion), MATRIX3 (three-dimensional matrix), MATRIX4 (four-dimensional matrix), BYTE_ARRAY (byte array), INT_ARRAY (integer array), DOUBLE_ARRAY (floating point array), STRING_ARRAY (string array), VECTOR2_ARRAY (two-dimensional vector array), VECTOR3_ARRAY (three-dimensional vector array), QUATERNION_ARRAY (quaternion array)};
compound type: {ENTITY_PROPERTY (entity type), COLLECTION_PROPERTY (collection type), CUSTOMENUM_PROPERTY (enumeration type), CUSTOMDATA_STRUCT (user-defined type)};
the attribute value of ENTITY_PROPERTY contains an entity ID, through which a corresponding entity can be found in an entity instance manager, and the entity ID is used to describe a relationship among entities such as a mounted entity, an assembled entity to a present entity, or an entity that the present entity is affiliated to;
the attribute value of COLLECTION_PROPERTY includes multiple properties, where the properties are of the above defined types, and are used to describe collections including physical components, spare parts of equipment maintenance warehouse, etc.;
the attribute of COLLECTION_PROPERTY includes an optional attribute value list and attribute values used for representing enumeration types such as order, equipment state and equipment working unit type;
the attribute of CUSTOMDATA_STRUCT is of user-defined type and is used to represent a set of attributes commonly used by users and facilitate attribute reuse; for instance, a user-defined equipment headcount attribute is named “Equipment Headcount”, and this attribute consists of equipment name, equipment ID, headcount quantity, actual quantity, etc.; once an equipment headcount attribute is set in an organization, the “Equipment Headcount” attribute defined above can be reused directly without repetitive defining;
the metadata is organized into a meta-model representation protocol, with physical module meta-model described in extensible markup language (XML), and an example of an XML specification of an equipment model is as follows:

```
<ENTITY Name= “certain equipment” Category= “equipmentlphysical modules | certain
equipment” Guid = “ 520ec0bb-d038-4353-8351-8f3d39ae3828”>
        <PropertySet>
          <Property Name=“service life” Type=“INT” Value=“2000” Unit=“motor hour”
          Scope=“ Model ”></Property>
          <Property Name=“headcount status” Type=“BOOL” Value=“1” Scope=
          “Instance”></Property>
          ......
        <Property Name=“component” Type=“COLLECTION_PROPERTY”
    Scope=“Instance” >
              <PropertySet>
                <Property Name=“engine” Type=“CUSTOMDATA_STRUCT”
                ModelName=“working unit” Guid=“ 32e5e4a3-8d90-4532-8819-
                4f2832367629”
                    <PropertySet>
                        <Property Name=“component code Value=“B0249” >
</Property>
                      <Property Name=“area” Value=“chassis part” > </Property>
                        ......
                    </PropertySet>
                  </Property>
            <PropertySet>
      </Property>
  </PropertySet>
</ENTITY>
```

in the above model, a module model with the model name “working unit” is referenced, and the attribute values of the model are set; an example of this module model is as follows:

```
<ENTITY Name= “certain working unit” Category= “equipment | physical module | working unit”
Guid = “32e5e4a3-8d90-4532-8819-4f2832367629”>
  <PropertySet>
    <Property Name=“component code” Type=“STRING” Value=“” Scope=
    “Instance ”></Property>
    <Property Name=“area” Type=“ STRING ” Value=“” Scope=
    “Instance”></Property>
    ......
  </PropertySet>
</ENTITY>
```

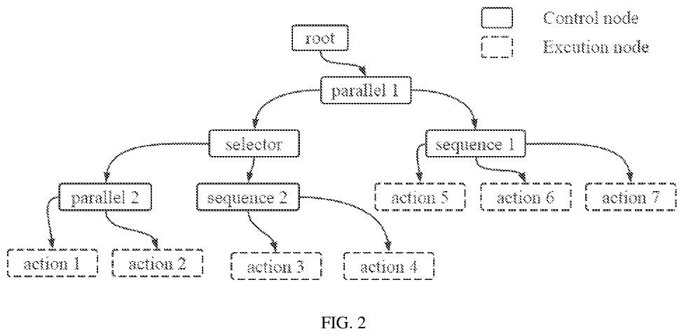

modeling of behavior attributes of simulation entities, including modeling entity behavior through a behavior tree, generating behavior modules, and constructing an event model for behavior to interact among entities with an event mechanism;
a BehaviourTree.CPP framework is used to establish an XML representation protocol of entity behavior tree as shown in FIG. 2, including mainly a modeling of its control nodes (including parallel nodes, serial nodes and selection nodes), execution nodes, execution preconditions of nodes and execution relationships among nodes; as each entity model module in this application has its own manager, and the modeling process is loosely coupled, the BehaviourTree.CPP framework is hence free to be replaced with other behavior tree frameworks according to the application requirements;
an event meta-model for an interaction among behavior-generated events and other entities is established; an event model is similar to a physical module and consists a series of basic attributes; for example, a training start event model XML exchange protocol is:

```
<EVENT Category=“equipment | event module | training event” Guid=“c3dc597a-b117-40a3-
9fbb46229d19dffb” Name=“training start event”>
  <PropertySet>
    <Property Name=“event ID” Type=“INT” Value=“1” Scope=“Model” ></Property>
    <Property Name=“event triggering event” Type=“LONGLONG” Value=“”
Scope=“Instance” Unit=“ms”></Property>
    ......
  </PropertySet>
</EVENT>
```

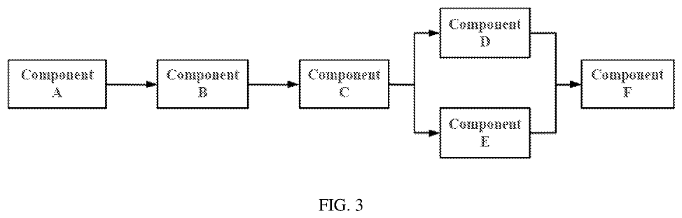

outside the entity, the execution node of behavior tree reads the XML protocol and generates an event instance, and interacts with other entities through the event mechanism to read and write attribute data of other entities; while within the entity, the behavior module reads and writes physical attribute data of the entity by sharing data with the physical module;
task reliability modeling, including modeling equipment task execution reliability by reliability block diagram (RBD) algorithm, and generating solid model task reliability module;
a reliability logic relationship of equipment modules under each task, including series connection, parallel connection, hybrid connection and parallel connection, etc. is analyzed on a basis of expert judgment, as shown in FIG. 3, where a the box represents module unit, and a connection line among the boxes represent the reliability logic relationship of component;
for common tandem systems, whenever one of the components fails, the system fails and the service life of the tandem system depends on the shortest one of the components; assuming that probabilities of failure of individual units are independent of each other and that a failure duration obeys an exponential distribution with failure rate λ, i.e., the failure rate of each unit is λ₁(t), . . . , λₙ(t), respectively, the reliability of the tandem system is:

$${R}_{S} ( t ) = {\prod }_{i = 1}^{n} {e}^{- {\int }_{0}^{t} {λ}_{i} ( t ) dt}$$

the failure rate of system is:

$${λ}_{S} = {\sum }_{i = 1}^{n} {λ}_{i} ( t )$$

and a mean time between failure (MTBF) of the system is:

MTBF_{S}=1/Σᵢ₌₁ⁿλᵢ(t)
in a parallel system, the system fails if all components fail, and the service life of the system depends on the longest one of the components; Rᵢ denotes the reliability of a component, and the reliability of the parallel system is:

$${R}_{S} = 1 - {\prod }_{i = 1}^{n} [ 1 - {R}_{i} ( t ) ]$$

a task RBD meta-model is established with XML, and shares physical component data with the physical modules; the RBD model XML of a certain equipment communication task is taken as an example:

```
< RBD Category= “equipment | task reliability module | certain equipment | communication task”
Guid= “b78f1d2a-9ec5-4a04-a0d9-b0d472cba083”Name = “communication training of certain
equipment” >
      <PropertySet>
        <Property Name=“available” Type=“BOOL” Scope=“Instance”
Value=“1”></Property>
        ......
  </PropertySet>
  <NodeSet>
      <Node Name=“engine” ID=“1” InNodeList=“” OutNodeList=“[2]”>
        <PropertySet>
          <Property Name=“component code” Type=“STRING” Scope=“Instance”
          Value=“A0013”></Property>
          <Property Name=“available” Type=“BOOL” Scope=“Instance”
          Value=“1”></Property>
          <Property Name=“running ratio” Type=“DOUBLE” Scope=“Instance”
          Value=“0.4”></Property>
            ......
        </PropertySet>
      </Node>
      <Node Name=“clutch” ID=“2” InNodeList=“[1]” OutNodeList=“[3]”>
        <PropertySet>
          <Property Name=“component code” Type=“STRING” Scope=“Instance”
          Value=“A0014″></Property>
          <Property Name=“available” Type=“BOOL” Scope=“Instance”
          Value=“1”></Property>
          <Property Name=“running ratio” Type=“DOUBLE” Scope=“Instance”
          Value=“0.0”></Property>
        </PropertySet>
      </Node>
        ......
    </NodeSet>
</ RBD >
```

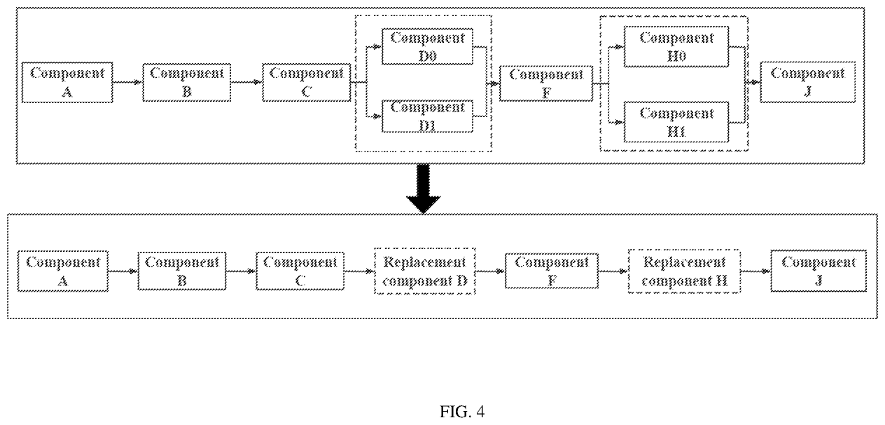

RBD is used in this implementation primarily to calculate whether a component affects system availability when it is not available; as shown in FIG. 4, a method for determining impact of a component on system availability by determining whether it is located in a tandem or parallel path of the RBD is illustrated as follows:
all nodes in the RBD with multiple outgoing edges are found, where Nₙ: {N₁, . . . , Nₘ};
posterior nodes Pₙᵢ of Nₙ are traversed with depth first until node Pₙⱼ with multiple incoming edges, and these paths are saved as Eₙ: {Pₙᵢ→Pₙⱼ};
all paths in Eₙ that have the same starting and ending points are the subparallel block diagram Gₙ; by removing Gₙ and replacing the position of Gₙ with a new node Tₙ, the availability of Tₙ is the availability of Gₙ;
the RBD block diagram contains only tandem paths after the previous step, where a system is not available if a node is not available, otherwise the system is available;
S3, a simulation entity model binding processing is carried out based on the attribute modeling of the simulation entity of a module to be tested, then a simulation entity model is obtained, the binding is implemented by a simulation entity model binding processing module in this embodiment;
a method of simulation entity model binding processing includes:
binding equipment physical module and the behavior modules corresponding to a task being performed as well as task reliability modules, and the binding is achieved through an association model globally unique identifier (GUID);
a method of task reliability modeling includes: modeling equipment task execution reliability by RBD algorithm, and generating solid model task reliability module;
specifically, each module is bound to generate a simulation entity model; after a simulation experiment is designed, an entity model is established by binding specific entity modules according to different tasks performed by the equipment entities;
based on the equipment task selected by the experimental design, the module manager is used to bind the equipment physical module to the behavior module and the task reliability module corresponding to the task it performs; an example of the bound model XML is shown below:

```
<Model Category=“” Name= “certain equipment instantiation model″ Guid=“52dce44b-ed2f-
4c0d-afb9-4825bffe1035”>
  <ENTITY Name-“certain equipment physical module” Guid=“520ec0bb-d038-4353-
  8351-8f3d39ae3828”></ENTITY>
  <BEHAVIOUR Name=“certain equipment behavior module” Guid=“972fc3ff-fa77-4lee-
  a05d-2cf7ef577380”></ BEHAVIOUR >
  <RBD Name=“a task reliability module of a certain equipment module” Guid=“c3dc597a-
  b117-40a3-9fbb-46229d19dffb”></ RBD >
</Model>
```

model manager is used for model management, and common models are persistently saved, without repeatedly binding of modules; and
S4, the simulation entity model is instantiated to obtain a simulation result, where the instantiation is performed by a simulation entity model instantiation module;
in the present embodiment, the specific entity instantiation is done by instantiating the entity model through an entity factory method to complete a simulation modeling process;
the simulation entity model is input into an instantiation factory, then an entity instance is output by a cloning method; and
the entity instance is managed with an instance manager to complete the modeling process; subsequently, the entity instance is loaded onto a simulation engine to run, and then the simulation process data is output for evaluation and optimization, and the simulation results are output.

Thus, the entire process of modularized modeling of equipment entities in simulation field based on meta-model is realized; in this way, it is feasible to loosely couple the simulation entity models with high generality.

According to the present application, the equipment entities are divided into three types of modules, including physical attributes, behavior attributes and task reliability attributes. Each module is represented based on a meta-model, composed of a description of metadata structure and semantics, the metadata is an abstract representation of the model and can be well reused in the field of simulation modeling. The modeling process of each module is loosely coupled, and the metadata of entity physical module contains a variety of basic data types and user-defined data types with good scalability; entity behavior module is expressed flexibly by behavior tree or state machine, etc.; entity task reliability module is modeled by EBD; after the simulation experiment is completed, the different modules are integrated to establish a complete entity model according to the different tasks performed by the entity, and the model is scalable and highly reusable with separated data, rules and algorithms.

The above described embodiments only describe the preferred way of this application, not to limit the scope of this application. Without departing from the spirit of the design of this application, all kinds of deformations and improvements made to the technical solution of this application by a person of ordinary skill in the art shall fall within the scope of protection determined by the claims of this application.

What is claimed is:

1. A method for modularized modeling of equipment entities in simulation field based on meta-model, comprising:
collecting data to be tested;
performing data pre-processing using the data to be tested, then obtaining metadata;
performing attribute modeling using the metadata, and obtaining a result of attribute modeling of a simulation entity of a module to be tested;
performing simulation entity model binding processing based on the result of attribute modeling of simulation entity, thus obtaining simulation entity model; and
instantiating the simulation entity model to obtain a simulation result.

2. The method for modularized modeling of equipment entities in simulation field based on meta-model according to claim 1, wherein the attribute modeling comprises: physical attribute modeling of simulation entity, behavior attribute modeling of simulation entity, and task reliability modeling.

3. The method for modularized modeling of equipment entities in simulation field based on meta-model according to claim 2, wherein the physical attribute modeling of simulation entity comprises attribute types of basic type and compound type;
the compound type comprises entity type, enumeration type and user-defined type;
the entity type comprises an entity primary key, used for indicating an inter-entity relationship among entities, comprising a mounted entity, an assembled entity to a present entity, or an entity that the present entity is affiliated to, then a corresponding entity is available in an entity instance manager through the entity primary key;
the enumeration type comprises optional attribute value list and attribute value, used for representing order enumeration type, equipment state enumeration type, and equipment working unit enumeration type; and
the user-defined type comprises an attribute list, the attribute list is commonly used by users and is convenient for attribute reuse.

4. The method for modularized modeling of equipment entities in simulation field based on meta-model according to claim 2, wherein a method of the behavior attribute modeling of simulation entity comprises: modeling entity behavior through a behavior tree, generating behavior modules, and constructing an event model for behavior to interact among entities with an event mechanism.

5. The method for modularized modeling of equipment entities in simulation field based on meta-model according to claim 2, wherein a method of the task reliability modeling comprises: modeling a reliability of equipment task execution through a reliability block diagram algorithm, and generating entity model task reliability module.

6. The method for modularized modeling of equipment entities in simulation field based on meta-model according to claim 1, wherein a method of the simulation entity model binding processing comprises: binding equipment physical module and the behavior modules corresponding to a task being performed as well as task reliability modules, and the binding is achieved through an association model globally unique identifier (GUID).

7. The method for modularized modeling of equipment entities in simulation field based on meta-model according to claim 1, wherein a method of instantiating the simulation entity model comprises: inputting the simulation entity model into an instantiation factory, outputting an entity instance by a cloning method, and managing the entity instance with an instance manager to complete a modeling process, then loading the entity instance onto a simulation engine, and running to output simulation results.

8. A system for modularized modeling of equipment entities in simulation field based on meta-model, comprising:
a metadata acquisition module, a simulation entity attribute modeling module, a simulation entity model binding processing module, and a simulation entity model instantiation module;
wherein the metadata acquisition module is used for acquiring metadata to be tested;
the simulation entity attribute modeling module is designed for performing attribute modeling based on the metadata, and obtaining a result of attribute modeling of a simulation entity of a module to be tested;
the simulation entity model binding processing module carries out simulation entity model binding processing based on the attribute modeling of the simulation entity of the module to be tested, then a simulation entity model is obtained; and
the simulation entity model instantiation module is used for instantiating the simulation entity model to obtain a simulation result.

9. The system for modularized modeling of equipment entities in simulation field based on meta-model according to claim 8, wherein the attribute modeling of simulation entity of the module to be tested in the simulation entity attribute modeling module comprises: simulation entity physical attribute modeling, simulation entity behavior attribute modeling and task reliability modeling.

10. The system for modularized modeling of equipment entities in simulation field based on meta-model according to claim 9, wherein a method of the simulation entity behavior attribute modeling in the simulation entity attribute modeling module comprises: modeling entity behavior through a behavior tree, generating behavior modules, and constructing an event model for behavior to interact among entities with an event mechanism.
